(19) United States
(12) Patent Application Publication
(10) Pub. No.: US 2026/0096488 A1
(43) Pub. Date: Apr. 2, 2026

(54) SEMICONDUCTOR STRUCTURE, CHIP PACKAGE STRUCTURE, AND COMPUTING DEVICE

(71) Applicant: Alibaba Damo (Hangzhou) Technology Co., Ltd., Hangzhou (CN)

(72) Inventors: Tianchan GUAN, Shanghai (CN); Dimin NIU, Sunnyvale, CA (US); Tianzhou JIANG, Shanghai (CN); Di WU, Beijing (CN); Hongzhong ZHENG, Los Gatos, CA (US); Jianfeng ZHANG, Hangzhou (CN)

(21) Appl. No.: 19/315,135

(22) Filed: Aug. 29, 2025

(30) Foreign Application Priority Data
Sep. 30, 2024 (CN) 202411389772.9

(51) Int. Cl. H01L 25/10; H01L 23/00; H01L 23/528

(52) U.S. Cl. CPC H10W 90/00; H10W 20/43; H10W 90/722; H10W 90/792

(57) ABSTRACT

A semiconductor structure includes a first wafer layer, where a first logic die and a second logic die are arranged along an extension direction of the first wafer layer; and a second wafer layer, formed with a third logic die, where the third logic die is stacked on one side of the first wafer layer. A first inter-die interface is configured between the first logic die and the third logic die, to enable the first logic die and the third logic die to perform data communication through the first inter-die interface. A second inter-die interface is configured between the second logic die and the third logic die, to enable the second logic die and the third logic die to perform data communication through the second inter-die interface. The first inter-die interface and the second inter-die interface are coupled through intra-die wiring of the third logic die.

### BACKGROUND

### Technical Field

Embodiments of the present specification relate to the field of integrated circuit technologies, and in particular, to a semiconductor structure, a chip package structure, and a computing device.

### Description of the Related Art

3D wafer-level packaging, which is also referred to as “vertical stack packaging”, is an advanced semiconductor packaging technology in which a chip package structure is obtained by stacking two or more wafer layers in a vertical direction, so that a function and performance of the chip package structure are significantly improved when a size of the chip package structure does not change. Different types of dies are made from wafers in semiconductor manufacturing processes and can be packaged in a same semiconductor package, to satisfy function requirements of the chip package structure on different wafer layers.

Specifically, after fine processing steps such as photo etching, etching, and doping, logic dies and storage dies may be separately fabricated from wafers. The logic die mainly includes a logic circuit, and is configured to form a processing unit that can perform high-performance calculation. The storage die is configured to form a storage unit such as an internal memory, and is responsible for storage and rapid reading and writing of data. The logic die and the storage die have different functions and designs, but are both key components in some chip package structures.

However, when the processing of a logic die has been completed, a size of the logic die has been determined, which limits a size of another die stacked on the logic die in the chip package structure. As a result, a computing power of the dies are limited, and the performance of the chip package structure is limited.

### BRIEF SUMMARY

Implementations of the present specification provide a semiconductor structure, a chip package structure, and a computing device, which resolve, among others, some problems of the existing solutions.

According to a first aspect of the embodiments of the present specification, a semiconductor structure is provided. The semiconductor structure includes a first wafer layer, where a first logic die and a second logic die are arranged along an extension direction of the first wafer layer; and a second wafer layer, formed with a third logic die, where the third logic die is stacked on one side of the first wafer layer. A first inter-die interface is configured between the first logic die and the third logic die, which enables data communication between the first logic die and the third logic die through the first inter-die interface. A second inter-die interface is configured between the second logic die and the third logic die, which enables data communication between the second logic die and the third logic die through the second inter-die interface. The first inter-die interface and the second inter-die interface are coupled through intra-die wiring of the third logic die.

In an implementation of the present specification, the first inter-die interface and the second inter-die interface share a third port of the third logic die, and the third port forms the intra-die wiring inside the third logic die. A first port of the first inter-die interface at the first logic die is coupled to the third port through first inter-die wiring, and a second port of the second inter-die interface at the second logic die is coupled to the third port through second inter-die wiring.

In an implementation of the present specification, the third port is disposed on a surface that is of the third logic die and that faces the first wafer layer, the first port of the first logic die is disposed on a surface that is of the first logic die and that faces the third port, and the second port of the second logic die is disposed on a surface that is of the second logic die and that faces the third port.

In an implementation of the present specification, the first port of the first logic die is disposed at an end that is of the first logic die and that is close to the second logic die, and the second port of the second logic die is disposed at an end that is of the second logic die and that is close to the first logic die.

In an implementation of the present specification, the first inter-die wiring is formed through hybrid bonding of the first port and the third port, and the second inter-die wiring is formed through hybrid bonding of the second port and the third port.

In an implementation of the present specification, the first port of the first inter-die interface at the first logic die includes a first interface controller, the second port of the second inter-die interface at the second logic die includes a second interface controller, and the first interface controller and the second interface controller are communicatively coupled through the third port.

According to a second aspect of the embodiments of the present specification, a chip level package structure is provided. The chip level package structure includes a first semiconductor structure and a package substrate. The first semiconductor structure includes a first wafer layer, where a first logic die and a second logic die are arranged along an extension direction of the first wafer layer; and a second wafer layer, formed with a third logic die, where the third logic die is stacked on one side of the first wafer layer. A first inter-die interface is configured between the first logic die and the third logic die, which enables data communication between the first logic die and the third logic die through the first inter-die interface. A second inter-die interface is configured between the second logic die and the third logic die, which enables data communication between the second logic die and the third logic die through the second inter-die interface. The first inter-die interface and the second inter-die interface are coupled through intra-die wiring of the third logic die. The package substrate is disposed on the other side of the first wafer layer.

In an implementation of the present specification, the chip package structure further includes a second semiconductor structure. The second semiconductor structure and the first semiconductor structure are disposed on a same side of the package substrate. An inter-component interface is configured between the first semiconductor structure and the second semiconductor structure. The inter-component interface is configured through inter-component wiring between the first semiconductor structure and the second semiconductor structure, to enable the first semiconductor structure and the second semiconductor structure to perform data communication through the inter-component interface.

In an implementation of the present specification, a port of the inter-component interface at the first semiconductor structure and a port of the inter-component interface at the second semiconductor structure form the inter-component wiring through internal wiring of the package substrate.

In an implementation of the present specification, the chip package structure further includes an interposer. The interposer is disposed between the package substrate and each of the first semiconductor structure and the second semiconductor structure. A port of the inter-component interface at the first semiconductor structure and a port of the inter-component interface at the second semiconductor structure form the inter-component wiring through internal wiring of the interposer.

In an implementation of the present specification, the first wafer layer includes at least two logic dies, and the at least two logic dies include the first logic die and the second logic die. A port of the inter-component interface at the first semiconductor structure is disposed on a logic die that is in the at least two logic dies of the first wafer layer and that is close to the second semiconductor structure.

In an implementation of the present specification, the second semiconductor structure includes at least a third wafer layer close to the package substrate. The third wafer layer includes at least two logic dies. A port of the inter-component interface at the second semiconductor structure is disposed on a logic die that is in the at least two logic dies of the third wafer layer and that is close to the first wafer layer.

In an implementation of the present specification, the first semiconductor structure further includes at least one fourth wafer layer. Each fourth wafer layer is formed as a storage die. The at least one fourth wafer layer is stacked on a side that is of the second wafer layer and that is away from the package substrate.

According to a third aspect of the embodiments of the present specification, a computing device is provided, including a processor unit. The chip package structure in the second aspect is integrated in the processor unit.

In the solutions of the embodiments of the present specification, the third logic die is stacked on a side of a first wafer layer that includes the first logic die and the second logic die, so that a size of the third logic die can be greater than a size of any one of the first logic die or the second logic die, and is compatible with a size of the second wafer layer. In addition, the first inter-die interface is configured between the first logic die and the third logic die, the second inter-die interface is configured between the second logic die and the third logic die, and the first inter-die interface and the second inter-die interface are coupled through the intra-die wiring of the third logic die, so that data communication can be formed between the first logic die and the second logic die, thereby improving a computing power of the first wafer layer, improving performance of the semiconductor structure, and further improving performance of the chip package structure.

### BRIEF DESCRIPTION OF THE SEVERAL VIEWS OF THE DRAWINGS

To describe the technical solutions in embodiments of the present specification or in the existing technologies more clearly, the following briefly describes the accompanying drawings required for describing the embodiments or the existing technologies. It is clear that the accompanying drawings in the following descriptions show merely a part of the embodiments of the present specification, and a person of ordinary skill in the art may still derive other drawings from the accompanying drawings.

FIG. 1 is a schematic diagram of a manner of configuring a wafer layer of a semiconductor structure according to some example advanced packaging technologies;

FIG. 2A is a schematic diagram of a structure of a semiconductor structure according to some embodiments of the present specification;

FIG. 2B is a schematic diagram of a structure of a chip package structure according to some embodiments of the semiconductor structure of FIG. 2A;

FIG. 2C is a schematic diagram of a structure of some example semiconductor structures according to an embodiment of FIG. 2A;

FIG. 2D is a schematic diagram of a structure of data access control performed by the semiconductor structure described in the embodiment of FIG. 2A;

FIG. 3 is a schematic diagram of a top view of the chip package structure according to the embodiment of FIG. 2B;

FIG. 4A is a schematic diagram of an example manner of configuring a wafer layer of a semiconductor structure according to the embodiment of FIG. 2A;

FIG. 4B is a schematic diagram of a side view of the chip package structure according to the embodiment of FIG. 2B; and

FIG. 5 is a schematic diagram of process parameters of manufacturing processes of different types of dies according to some other embodiments of the present specification.

### DETAILED DESCRIPTION

To enable a person skilled in the art to better understand the technical solutions of embodiments of the present specification, the technical solutions of the embodiments of the present specification will be described clearly and thoroughly below with reference to the accompanying drawings of the embodiments of the present specification. It is clear that the described embodiments are merely a part of the embodiments of the present specification but are not all of the embodiments. All other embodiments obtained by a person of ordinary skill in the art based on the embodiments of the present specification shall fall within the protection scope of the embodiments of the present specification.

Example implementations of the embodiments of the present specification are further described below with reference to the accompanying drawings of the embodiments of the present specification.

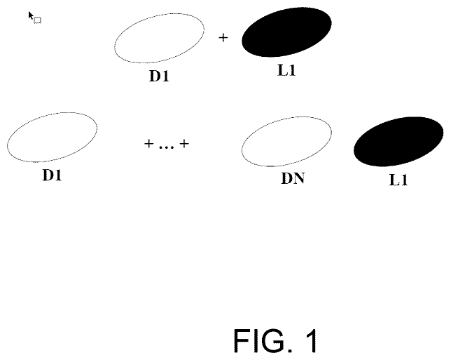

With the development of electronic devices toward further miniaturization and higher performance, 3D wafer-level packaging becomes a key factor promoting the trend. The 3D wafer-level packaging not only can provide a larger on-die storage capacity to support increasingly high requirements on data storage and processing, but also can improve a signal transmission speed and reduce power consumption by reducing an external connection of a component. For example, a semiconductor structure obtained through 3D wafer-level packaging in FIG. 1 can provide higher chip integration and higher space utilization, and can further improve chip electrical performance and thermal management efficiency. In a wafer-level package configuration in FIG. 1, each wafer layer may include one or more logic dies or one or more storage dies. In FIG. 1, a storage die is represented by using a hollow ellipse (for illustration purposes only), and a logic die is represented by using a solid ellipse (for illustration purposes only). The logic die mainly includes a logic circuit, and is configured to form a processing unit that can perform high-performance calculation. The storage die is configured to form a storage unit such as an internal memory, and is used for storage and rapid reading and writing of data.

For example, in a wafer-layer configuration of a semiconductor structure (A) of the semiconductor structure, a wafer layer formed by using a logic die (L1) and a wafer layer formed by using a storage die (D1) are stacked to obtain the semiconductor structure. The storage die D1 may include a storage unit such as a DRAM (Dynamic Random Access Memory, dynamic random access memory), and the logic die L1 may include a logic unit such as a PE (processing element). In this case, corresponding to a given computing-power resource of the logic die, an accessed storage resource can still be increased.

In addition, in a wafer-layer configuration (B) of a semiconductor structure, a wafer layer formed by using a logic die (L1) and a plurality of wafer layers of N storage dies (D1, . . . , DN) are stacked to obtain the semiconductor structure. The plurality of wafer layers of the plurality of storage dies can form an internal memory such as dynamic random access memories (DRAMs) stacked in a three-dimensional manner, to provide a storage resource for the logic die L1. A computing-resource in the logic die L1 can be used to access storage resources of the storage dies D1-DN in the plurality of the wafer layers. When the processing of the logic die has been completed, a size of a wafer layer of the logic die has been determined, which limits a size of a storage die stacked on the logic die in the chip package structure. In addition, routing and access control of the storage resources of the storage dies of the plurality of wafer layers occupy a large quantity of computing resources. As a result, a proportion of computing resources used by the logic die for actual operations is reduced.

The present specification provides embodiments of semiconductor packaging, which can be compatible with sizes of wafer layers, and improve performance of the chip level package structure.

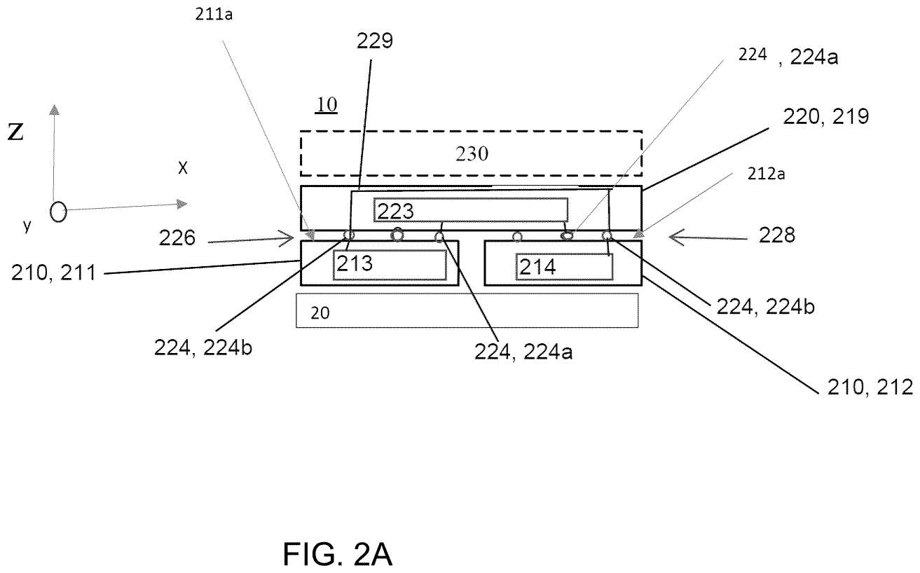

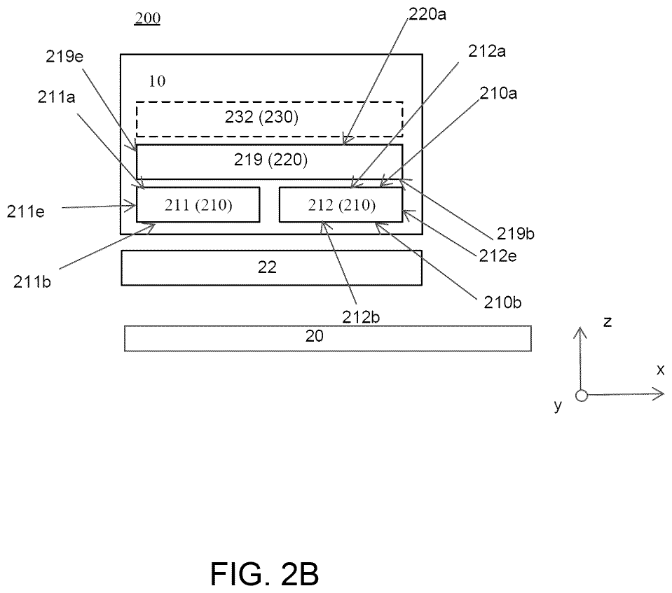

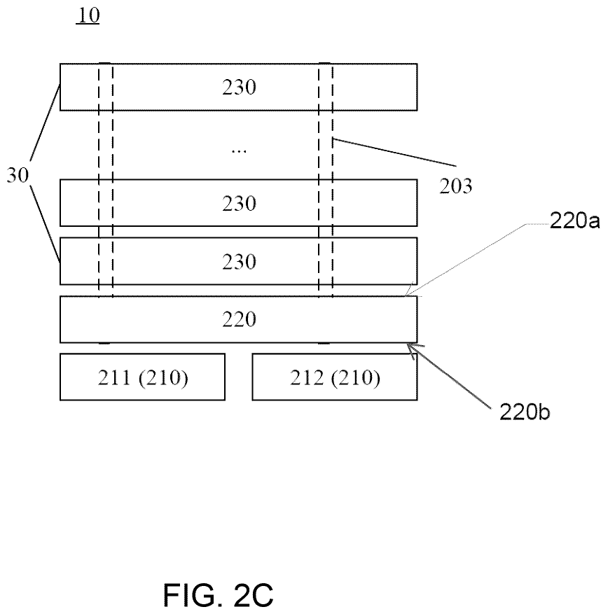

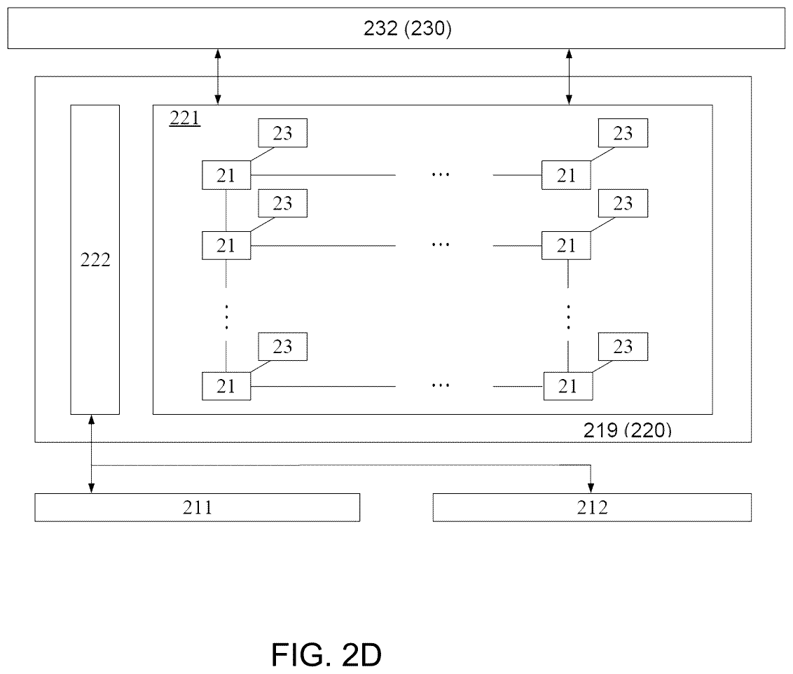

FIG. 2A shows a semiconductor structure according to some embodiments of the present specification. A semiconductor structure 10 includes a first wafer layer 210 and a second wafer layer 220. The second wafer layer 220 is disposed on one side of the first wafer layer 210, e.g., along the z-axis direction. In some implementations, a package substrate 20 may be disposed on the another side of the first wafer layer 210, e.g., along the z-axis direction.

For example, at the first wafer layer 210, at least two logic dies 211, 212 are arranged along a lateral extension direction, e.g., x-axis direction, of the first wafer layer 210.

In addition, the second wafer layer 220 is formed with a third logic die 219. The third logic die 219 is stacked on a side 211a, 212a of each of the at least two logic dies 211, 212, and corresponds to the at least two logic dies 211, 212.

In some implementations, the third logic die 219 is at least partially aligned with one or more of the first logic die 211 and the second logic die 212 in a stacking direction, e.g., the z-axis direction, of the first wafer layer 210 and the second wafer layer 220. For example, a die area of the third logic die 219 is equal to or greater than a die area of the first logic die 211 and a die area of the second logic die 212. For example, when die areas of the first logic die and the second logic die are the same, a die area of the third logic die is at least twice the die area of the logic die. In some implementations, the third logic die 219 is partially offset from one or more of the first logic die 211 or the second logic die 212 such that an edge surface 219e of the third logic die 219 does not align with edge surfaces 211e, 212e of either one of the first logic die 211 or the second logic die 212.

For example, at least two logic dies are disposed at the first wafer layer 210, and the at least two logic dies include the first logic die 211 and the second logic die 212. When two or more logic dies are disposed at the first wafer layer 210, the die area (surface area) of the third logic die 219 can be greater than the die area of any one of the is approximately twice a die area of each of the logic dies. When four logic dies are disposed at the first wafer layer, the die area of the third logic die is approximately four times of a die area of each of the logic dies.

In addition, through a wafer manufacturing and packaging process, a logic device is disposed in the first logic die, a logic device is disposed in the second logic die, and a logic device is disposed in the third logic die.

It should be further understood that the first wafer layer 210 may be coupled to the second wafer layer 220 through hybrid bonding 224. For example, first bonding points are disposed on surfaces of the first logic die 211 and the second logic die 212 of the first wafer layer 210 and that are opposite to or facing the second wafer layer 220, and second bonding points are disposed on a surface of the third logic die 219 of the second wafer layer that is opposite to or facing the first wafer layer, so that positions of the first bonding points correspond to positions of the second bonding points. In the first semiconductor structure, hybrid bonding is achieved on the first wafer layer and the second wafer layer by using position correspondences between the first bonding points and the second bonding points. The first bonding points and the second bonding points may be one or more of solder bumps, connection pads, connection adhesives, or other interconnection features. In some implementations, the first bonding points and the second bonding points may be different types of interconnection features from one another. In some implementations, one of the first bonding points or the second bonding points are external to the logic dies 211, 212, 222, and another one of the first bonding points or the second bonding points are embedded in the surface of the logic dies 211, 212, 222.

A first inter-die interface 226 is configured between the first logic die 211 and the third logic die 222, which enables data or signal communication between the first logic die 211 and the third logic die 219 through the first inter-die interface 226. A second inter-die interface 228 is configured between the second logic die 212 and the third logic die 222, which enables data or signal communication between the second logic die 212 and the third logic die 219 through the second inter-die interface 228. The first inter-die interface 226 and the second inter-die interface 228 are coupled through intra-die wiring 229 in the third logic die 219.

In some implementations, the first inter-die interface 226 is formed between the first logic die 211 and the third logic die 219 through a first portion of the hybrid bonding 224 (second hybrid bonding), and a part 224a of the first hybrid bonding is used for data transmission between the logic device 213 in the first logic die 211 and the logic device 223 in the third logic die 219. The second inter-die interface 228 is formed between the second logic die 212 and the third logic die 219 through a second portion of the hybrid bonding 224 (second hybrid bonding), and a part 224a of the second hybrid bonding is used for data transmission between the logic device 214 in the second logic die 212 and the logic device 223 in the third logic die 219. In some examples, the intra-die wiring 229 of the third logic die is coupled between another part 224b of the first hybrid bonding and another part 224b of the second hybrid bonding, to form data transmission between the logic device 213 in the first logic die 211 and the logic device 214 in the second logic die 212 without the logic device 223 in the third logic die 219.

FIG. 2B shows a chip package structure of some other embodiments including the semiconductor structure shown in FIG. 2A. A chip package structure 200 in FIG. 2B includes a first semiconductor structure 10 and a package substrate 20.

The first semiconductor structure 10 includes a first wafer layer 210 and a second wafer layer 220. The second wafer layer 220 is disposed on a first side 210a of the first wafer layer 210, and the package substrate 20 is disposed on a second side 210b of the first wafer layer 210. In some implementations, sides 210a, 210b are opposite to one another.

For example, at the first wafer layer 210, at least two logic dies 211, 212 are arranged along a lateral extension direction of the first wafer layer 210, and the package substrate 20 is disposed on the sides 211b, 212b of the at least two logic dies 211, 212. The sides 211b and 212b are at a same level, e.g., coplanar, with one another.

The second wafer layer 220 is formed with at least one third logic die 219. The third logic die 219 is stacked on sides 211a, 212a of the at least two logic dies 211, 212, and corresponds to the at least two logic dies. The sides 211b and 212b are at a same level, e.g., coplanar, with one another.

In addition, the first semiconductor structure 10 further includes at least one third wafer layer 230. For example, the third wafer layer 230 may include at least one semiconductor die 232 of a memory device such as a dynamic random access memory (DRAM). For example, each third wafer layer 230 is formed as a storage die, and a plurality of storage dies may form a stacked structure of a plurality of memories. In some implementations, the at least one third wafer layer 230 is stacked on a side 220a of the second wafer layer 220 that is distal from the package substrate 20. For example, the second wafer layer 220 is stacked between the first wafer layer 210 and the at least one third wafer layer 230. In some implementations, a die size or die area of the storage die 232 is the same as a die size or die area of the third logic die 219. In a stacking direction, e.g., z-axis, of each wafer layer 210, 220, 230, one storage die 232 or a plurality of stacked storage dies 232 are corresponding to, e.g., aligned with, the third logic die 219.

It should be understood that, in the chip package structure, the first logic die 211 and the second logic die 212 may be directly stacked side by side on the package substrate 20, or directly stacked at an interposer 22 that is positioned between the first wafer layer 210 and the package substrate 20. For example, the first logic die 211 and the second logic die 212 may be stacked on the package substrate 20 through the interposer 22. A plurality of semiconductor structures or a plurality of dies may be arranged side by side or stacked on the interposer 22 and/or on the package substrate 20. For example, in an advanced packaging process such as 2.5D wafer-level packaging, an electrical connection is established between an interposer and a die, between a die and a package substrate, between dies arranged laterally or vertically with respect to one another, or between an interposer and a package substrate semiconductor structure by using micro-bumps (e.g., solder bumps) and/or a redistribution layer (Redistribution Layer, RDL). For example, in an advanced packaging process such as 2D wafer-level packaging, an electrical connection is established between a package substrate and a die that is at a lowest layer of a semiconductor structure by using bumps (bumps) and/or wirings, and various electrical connections are coupled through internal wiring inside the package substrate. In the solutions of the embodiments of the present specification, the third logic die 219 is stacked on the side 210a of the first wafer layer 210 that includes the first logic die 211 and the second logic die 212, so that a size of the third logic die can be greater than a size of any one of the first logic die 211 or the second logic die 212, and is compatible with a size of the second wafer layer 220. In addition, the first inter-die interface 226 (FIG. 2A) is configured between the first logic die 211 and the third logic die 219, the second inter-die interface 228 (FIG. 2A) is configured between the second logic die 212 and the third logic die 219, and the first inter-die interface 226 and the second inter-die interface 228 are coupled through the intra-die wiring 229 (FIG. 2A) of the third logic die, so that the first logic die 211 and the second logic die 212 can perform data communication with each other, thereby improving a computing power of the first wafer layer 210, improving performance of the semiconductor structure 10, and further improving performance of the chip package structure 200.

In some embodiments, a part of the first hybrid bonding 224 (FIG. 2A) is used for data transmission between the logic device in the first logic die 211 and the logic device in the third logic die 219, a part of the second hybrid bonding 224 is used for data transmission between the logic device in the second logic die 212 and the logic device in the third logic die 219, and the intra-die wiring 229 (FIG. 2A) of the third logic die 219 is coupled between another part of the first hybrid bonding and another part of the second hybrid bonding, to form data transmission between the logic device in the first logic die 211 and the logic device in the second logic die 212, so that a packaging process of the first hybrid bonding and the second hybrid bonding is compatible. For example, a logic device 223 may be disposed in a space outside of internal wirings inside the third logic die 219, and the logic device 223 in the third logic die 219 may be configured with a logic function, which can have data transmission with one or more of the logic device 213 in the first logic die 211 or the logic device 214 in the second logic die 212.

In some embodiments, as shown in FIG. 2C, the semiconductor structure 10 includes a stacked structure 30 formed by a plurality of third wafer layers 230. The stacked structure 30 is disposed on a side 220a of the second wafer layer 220 having the third logic die 219. The first wafer layer 210 is disposed on a side 220b of the second wafer layer 220. The first wafer layer 210 includes the first logic die 211 and the second logic die 212. In some implementations, sides 220a, 220b are opposite to one another.

The stacked structure 30 may be provided with a through silicon via (TSV) 203 communicating the plurality of third wafer layers 230. The through silicon via 203 is configured to connect the storage die 232 in each of the third wafer layer 230 to one another and further to one or more of the third logic die 219 at the second wafer layer 220 or the first logic die 211, or the second logic die 212 at the first wafer layer 210, to transmit data between the storage die 232 and the logic dies 222, 211, 212.

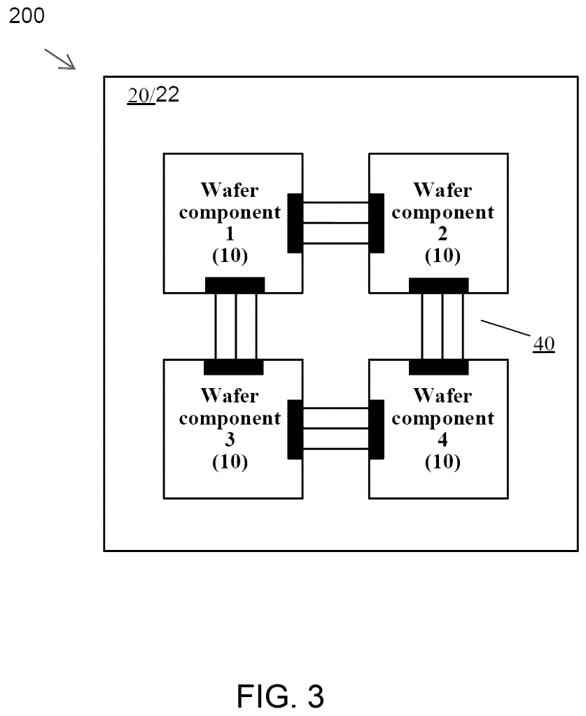

In some embodiments, the chip package structure 200 includes a plurality of semiconductor structures 10. As shown in FIG. 3, the chip package structure 200 includes a semiconductor structure 1, a semiconductor structure 2, a semiconductor structure 3, a semiconductor structure 4, and a package substrate 20. The semiconductor structure 1, the semiconductor structure 2, the semiconductor structure 3, and the semiconductor structure 4 are disposed on a same side of the package substrate 20. For example, each of the semiconductor structures 10 may be directly disposed on the package substrate 20, or each of the semiconductor structures 10 is directly disposed at an interposer 22, and is disposed on the package substrate 20 through the interposer 22.

In an example in which each of the semiconductor structures 1, 2, 3, 4 is disposed on the package substrate 20 through the interposer 22, in an advanced packaging process such as 2.5D wafer-level packaging, a plurality of semiconductor structures or a plurality of dies may be arranged side by side or stacked at the interposer or on the package substrate. For example, an electrical connection is established between an interposer and a die that is at a lowest layer of a semiconductor structure by using micro-bumps (micro-bumps), and side by side interconnection between the die and a package substrate is implemented by using a redistribution layer (Redistribution Layer, RDL). Therefore, an interconnection density between different semiconductor structures is improved, and a signal transmission path is shortened, thereby reducing power consumption and a delay, and improving a data transmission rate. Still further, in an advanced packaging process such as 2.5D wafer-level packaging, a plurality of semiconductor structures may be arranged side by side at an interposer 22 such as a silicon interposer by using a CoWoS (Chip on Wafer on Substrate) packaging process, thereby achieving a higher interconnection density and better performance between different semiconductor structures. In the CoWoS packaging process, each semiconductor structure may be coupled to the silicon interposer by using micro-bumps (micro-bumps), to form a chip on wafer (CoW) structure. The CoW structure is thinned, so that a through silicon via is exposed to form C4 bumps, and cutting is performed to form individual semiconductor structures. Then, the semiconductor structures are further bonded to the package substrate 20, to obtain a CoWoS package.

In an example in which each of the semiconductor structures 1, 2, 3, 4 is directly disposed on the package substrate 20, in an advanced packaging process such as 2D wafer-level packaging, an electrical connection is established between the package substrate 20 and a die 211, 212 that is at a lowest layer of a semiconductor structure by using bumps (solder bumps), pads, pins, or wires, and various electrical connections can also be coupled through internal wiring inside the package substrate 20.

In other words, without loss of generality, the chip package structure includes a first semiconductor structure (one of 1, 2, 3, 4) and a second semiconductor structure (another one of 1, 2, 3, 4). The second semiconductor structure 2 and the first semiconductor structure 1 are disposed on a same side of the package substrate 20. An inter-component interface 40 is configured between the first semiconductor structure 1 and the second semiconductor structure 2. The inter-component interface 40 is configured through inter-component wiring between the first semiconductor structure 1 and the second semiconductor structure 2, to enable the first semiconductor structure 1 and the second semiconductor structure 2 to perform data communication through the inter-component interface 40. In other words, in the chip package structure 200, the second semiconductor structure 2 and the first semiconductor structure 1 are disposed on the same side of the package substrate 20, so that different semiconductor structures can be processed independently. In addition, the different semiconductor structures may communicate with each other through the inter-component interface, thereby improving computing performance of the chip package structure.

In some implementations, the semiconductor structures 1, 2, 3, 4 are same semiconductor structures. In some implementations, one or more of the semiconductor structures 1, 2, 3, 4 are different from other ones of the semiconductor structures 1, 2, 3, 4.

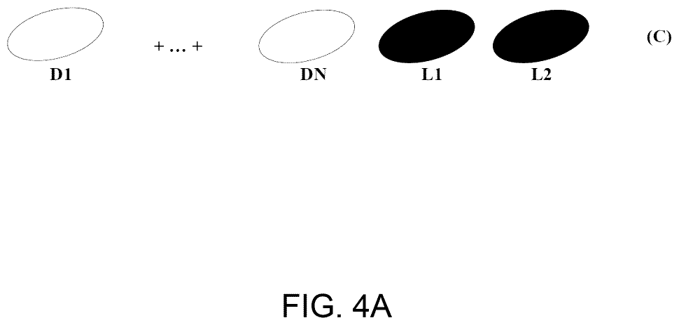

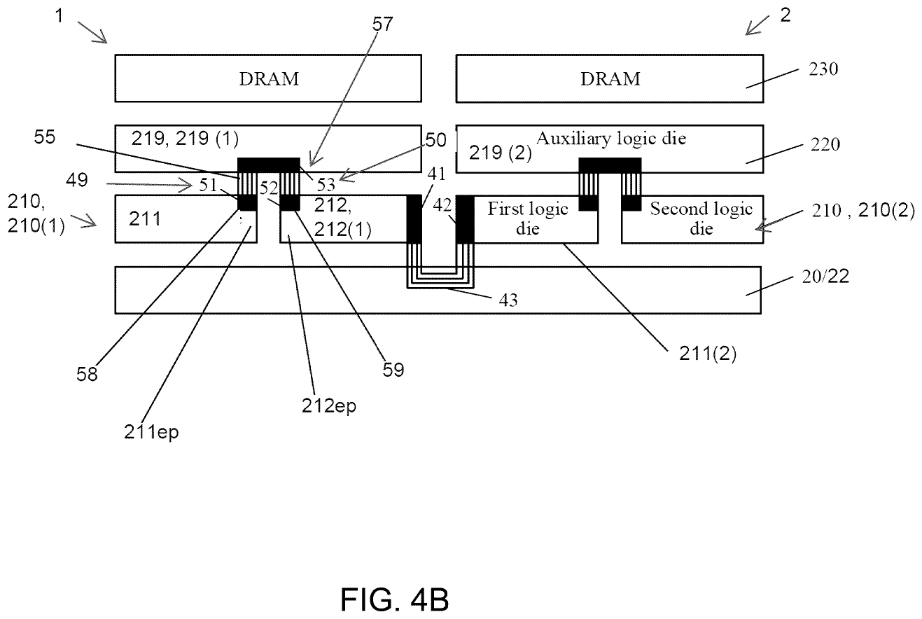

Further, FIG. 4A shows a wafer-layer configuration (C) of the semiconductor structure 10. Each wafer layer of the semiconductor structure 10 includes a first wafer layer (shown as L2) formed by a first logic die and a second logic die, a second wafer layer (L1) formed by a third logic die, and a plurality of third wafer layers of a plurality of storage dies (shown as D1, . . . , DN). The wafer layers are stacked to obtain the semiconductor structure 10. Computing-power resources in the first logic die and the second logic die can be used to access storage resources of the storage dies in the plurality of wafer layers through the third logic die. A logic unit in the third logic die may be configured as an internal memory controller of the plurality of storage dies. For example, when the internal memory controller routes between storage units in the storage dies, the internal memory controller is coupled to an access node in each of the storage dies through inter-layer wiring of different wafer layers, so that the internal memory controller first routes a data access instruction to an access node of a corresponding storage die, and the access node routes the data access instruction to a corresponding storage device through intra-die wiring in the storage die.

Without loss of generality, the first semiconductor structure further includes at least one third wafer layer. Each third wafer layer is formed as a storage die. The at least one third wafer layer is stacked on a side that is of the second wafer layer and that is away from the package substrate. In some cases, the at least one third wafer layer is a plurality of third wafer layers. To be specific, as a requirement on data processing efficiency of a semiconductor structure increases, the plurality of third wafer layers are stacked to form a stacked structure such as dynamic random access memories (DRAMs) stacked in a three-dimensional manner. Consequently, a problem of insufficient computing resources of the logic die is highlighted. In addition, a size or an area of the storage die in an extension direction of the third wafer layer may be greater than a size or an area of the first logic die or the second logic die in a lateral extension direction of the second wafer layer, so that an access bandwidth of the storage device in the storage die can be further improved when storage space of the storage die is ensured. For example, the area of the storage die may be twice that of the first logic die or the second logic die. In the semiconductor structure, the first wafer layer and the plurality of third wafer layers are stacked in this manner, and the third logic dies may be set to be aligned with the first logic die and the second logic die in a stacking direction, thereby improving compactness and integration of the semiconductor structure.

In addition, when the second wafer layer L1 is lacked, if the first wafer layer L2 and the plurality of third wafer layers D1 . . . DN are stacked in the foregoing manner, both the first logic die and the second logic die can access memories formed by the plurality of third wafer layers D1 . . . DN. For example, the first logic die and the second logic die may use the plurality of third wafer layers as shared memories to perform distributed computing. Further, when the second wafer layer L1 is stacked between the first wafer layer L2 and the plurality of third wafer layers D1 . . . DN, the first logic die and the second logic die of the first wafer layer L2 can be enabled to communicate by using the third logic die at the second wafer layer, thereby balancing computing performance of the first logic die and the second logic die. For example, when a computation amount of the first logic die is large, at least a part of computation tasks may be delivered to the second logic die, that is, the second logic die serves as a downstream computing node of the first logic die, and the first logic die serves as an upstream computing node of the second logic die.

In some other embodiments, in an example of access control over the storage die, as shown in FIG. 2D, the third logic die 219 at the second wafer layer 220 includes a logic array 221 and a program memory 222. The logic array 221 includes a routing node for a memory block in the stacked structure 30, and the routing node is coupled to a memory block in the storage die 232 at the third wafer layer 230 through wiring in the through silicon via 203 between the plurality of third wafer layers in the stacked structure 30.

The logic array 221 includes a plurality of switches 21 and a plurality of arithmetic logic units 23. The logic array 221 may receive a data access instruction from the first logic die 211 and/or the second logic die 212 by using the program memory 222. The data access instruction instructs to access the storage die at the third wafer layer 230 in the stacked structure 30.

For example, the data access instruction may include a command for configuring the switches 21, a command for accessing the storage die in the stacked structure 30, and a command for operating the arithmetic logic units 23. Correspondingly, the program memory 222 may receive the data access instruction from the first logic die 211 through the first inter-die interface, or receive the data access instruction from the second logic die 212 through the second inter-die interface. Then, the program memory 222 configures the switches 21 and indicates an operation of the arithmetic logic units 23 corresponding to the switches 21. The switches 21 create data paths and guide data flows, and the corresponding arithmetic logic units 23 perform data access such as write access or read access based on the guided data flows.

In some examples, the program memory 222 may be implemented as a static random access memory (SRAM). In other examples, the program memory 222 may be implemented as any suitable program memory on the third logic die.

In some implementations, logic devices such as the logic array 221 and the program memory 222 may be disposed in a space separate from the internal wiring 229 inside the third logic die, so that the logic devices such as the logic array 221 and the program memory 222 serve as the internal memory controller of the plurality of storage dies 232. For example, at least one memory block may be configured in the storage die 232 at the third wafer layer 230 of the stacked structure 30, to form a memory device such as a dynamic random access memory (DRAM).

For example, in a process in which the memory block in the stacked structure 30 is accessed, a memory address for access of the memory block includes a memory block identifier and an address offset in the memory block. In some examples, memory blocks located in a same storage die 232 may have a same head address, and different memory blocks in the same storage die 232 have different address offsets. In some examples, routing nodes in the logic array 221 that correspond to the memory blocks in the same storage die 232 may be located in a same row or a same column in the logic array 221.

Further, when the routing node of the logic array 221 is configured with the switch 21 and the arithmetic logic unit 22, the switch 21 may correspond to at least one memory block in the stacked structure 30. For example, the switch 21 is coupled to a memory block in the storage die 232 at the third wafer layer through the through silicon via 203 between the plurality of third wafer layers 230 in the stacked structure 30.

In addition, the logic device 213 in the first logic die 211 may send a data access instruction to the program memory 222 through a part of the first hybrid bonding 226, or the logic device 214 in the second logic die 212 may send a data access instruction to the program memory 222 through a part of the second hybrid bonding 228. Then, in response to the data access instruction, the program memory 222 configures the switch 21 to create a data path and guide a data flow, and indicates the arithmetic logic unit 22 corresponding to the switch 21 to access, based on the guided data flow, a storage die 232 at a corresponding third wafer layer 230. In some examples, the program storage 222 may parse the data access instruction, determine a memory block corresponding to a memory address (for example, a memory block identifier corresponding to the memory address), and configure the switch 21 to create the data path and guide the data flow to the corresponding memory block.

In some examples, the first logic die 211 and the second logic die 212 can perform parallel computing. For example, the logic device 213 in the first logic die 211 may send a computing instruction to a third port of the third logic die 219 through part 224b of the first hybrid bonding 226, and the third port of the third logic die forwards, through the intra-die wiring 229, the computing instruction to the logic device 214 in the second logic die 212 through part 224b of the second hybrid bonding 228, so that the logic device 214 in the second logic die 212 executes the computing instruction. For another example, the logic device 213 in the first logic die 211 may send a data access instruction to the program memory 222 of the third logic die 219 through the first inter-die interface 226. After reading data from a corresponding memory block of the storage die 232 in response to the data access instruction, the program memory 222 returns the data to the logic device 214 in the second logic die 212 through the second inter-die interface 228.

As shown in FIG. 3, in each of the semiconductor structures 1, 2, 3, 4, an inter-component interface 40 may be disposed between adjacent semiconductor structures 1, 2, 3, 4. As shown in FIG. 4B, the adjacent semiconductor structures 1, 2, 3, 4 are the first semiconductor structure 1 and the second semiconductor structure 2. A port 41 of the inter-component interface 40 at the first semiconductor structure 1 and a port 42 of the inter-component interface 40 at the second semiconductor structure 2 are coupled through inter-component wiring 43, to form a physical layer of the inter-component interface 40.

In some examples, some of the semiconductor structures 1, 2, 3, 4 may be directly disposed on the package substrate 20 (or on the interposer 22), and the inter-component wiring 43 is disposed inside the package substrate 20 (or the interposer 22). For example, the port 41 of the inter-component interface 40 at the first semiconductor structure 1 and the port 42 of the inter-component interface 40 at the second semiconductor structure 2 are coupled through the inter-component wiring 43 through internal wiring of the package substrate 20 (or the interposer 22). As such, area space occupied between different semiconductor structures by the inter-component wiring is reduced through the internal wiring of the package substrate 20 (or interposer 22).

In some examples, some of the semiconductor structures 1, 2, 3, 4 is directly disposed at the interposer 22, and the inter-component wiring 43 may be disposed in the interposer 22. For example, the interposer 22 is disposed between the package substrate 20 and the first semiconductor structure 1 and the second semiconductor structure 2. The port 41 of the inter-component interface 40 at the first semiconductor structure 1 and the port 42 of the inter-component interface 40 at the second semiconductor structure 2 are coupled through the inter-component wiring 43 through internal wiring of the interposer 22. Data transmission efficiency between different semiconductor structures is improved through the internal wiring of the interposer 22. In addition, the internal wiring of the interposer 22 is used to replace the internal wiring of the package substrate 20, to implement the inter-component wiring, so that a manufacturing thickness of the package substrate can be reduced, thereby reducing a thickness of the chip package structure.

As shown in FIG. 4B, the inter-component interface 40 is disposed between the first wafer layer 210(1) of the semiconductor structure 1 and the first wafer layer 210(2) of the second semiconductor structure 2. For example, the port 41 of the inter-component interface 40 at the first semiconductor structure 1 is disposed on the second logic die 212(1) at the first wafer layer 210(1), and the port 42 of the inter-component interface 40 at the second semiconductor structure 2 is disposed on the first logic die 211(2) at the first wafer layer 210(2). Without loss of generality, the port 41 of the inter-component interface 40 at the first semiconductor structure 1 is disposed on a logic die that is in the at least two logic dies of the first wafer layer and that is close to the second semiconductor structure 2, to help reduce a physical distance between the port 41 of the first semiconductor structure 1 and the second semiconductor structure 2, thereby reducing a length of the inter-component interface 40. In addition, the second semiconductor structure 2 includes at least a first wafer layer 210(2) close to the package substrate. The first wafer layer 210(2) includes at least two logic dies. A port 42 of the inter-component interface 40 at the second semiconductor structure 2 is disposed on a logic die 211(2) that is in the at least two logic dies of the first wafer layer 210(2) and that is close to the first wafer layer 210(1) of the first semiconductor structure 1, to help reduce a physical distance between the port 42 of the second semiconductor structure 2 and the first semiconductor structure 1, thereby reducing the length of the inter-component interface 40.

In addition, the port 41 of the inter-component interface 40 at the first semiconductor structure 1 and the port 42 of the inter-component interface 40 at the second semiconductor structure 2 may be communicatively coupled by using an inter-component wiring or interconnect bus 43 such as a universal chiplet interconnect express (Universal Chiplet Interconnect express, UCIe). Protocol layers of the UCIe include a physical layer, an adaptation layer, and a transport layer. The physical layer transmits, by using wiring of the inter-component interface 40, a signal carrying data. The adaptation layer is configured to manage a link status of the inter-component interface 40, for example, CRC and a link-layer retry mechanism. The transport layer is configured to convert, for example, through data mapping or wiring channel repairing, a format of a data packet transmitted by the inter-component interface 40 into a format suitable for transmission at the physical layer.

Further, as shown in FIG. 4B, in the semiconductor structure 10, the third logic die (also referred to as an auxiliary logic die) 219 is formed at the second wafer layer 220, and the third logic die 219(1), 219(2) may serve as an auxiliary logic die for the respective first logic die 211 and the second logic die 212 in the same semiconductor structure 1, 2.

In some examples, there is a first inter-die interface 49 between an auxiliary logic die 219 (shown with respect to auxiliary logic die 219(1)) and the respective first logic die 211, and there is the second inter-die interface 50 between the auxiliary logic die 219 and the respective second logic die 212. Therefore, the third logic die 219 serving as the auxiliary logic die may separately perform data transmission with the first logic die 211 and with the second logic die 212. In addition, the auxiliary logic die 219 is provided with a data transmission path between the first inter-die interface and the second inter-die interface. For example, as shown in FIG. 4B, a first port 51 of the first inter-die interface 49 is formed at the first logic die 211, and a second port 52 of the second inter-die interface 50 is formed at the second logic die 212. The first inter-die interface 49 and the second inter-die interface 50 share or are both coupled to a third port 53 at the auxiliary logic die, and the third port 53 forms the data transmission path.

For example, the third port or the data transmission path 53 includes a physical layer connection used for data transmission, and a control logic configuration based on the physical layer connection.

For the physical layer connection, the third port 53 may form the intra-die wiring inside the third logic die 219. The first inter-die interface 49 and the second inter-die interface 50 share the third port 53 of the third logic die 219, and the third port 53 forms the intra-die wiring inside the third logic die 219. The first port 51 of the first inter-die interface at the first logic die 211 is coupled to the third port 53 through first inter-die electrical coupling or wiring, and the second port 52 of the second inter-die interface 50 at the second logic die 212 is coupled to the third port 53 through second inter-die coupling or wiring 57. The first inter-die wiring 55 improves data transmission efficiency of the first inter-die interface 49, and the second inter-die wiring 57 improves data transmission efficiency of the second inter-die interface 50. Further, the intra-die wiring or the third port 53 connects the first inter-die coupling or wiring 55 to the second inter-die coupling or wiring 57, thereby implementing physical layer connection between the first port 51 and the second port 52, and improving data transmission efficiency between the first port and the second port. In some implementations, the first inter-die coupling or wiring 55 and the second inter-die coupling or wiring 57 are implemented through portions of the hybrid bonding 224.

In some examples, with reference also to FIG. 2B, the third port 53 is disposed on a surface 219b of the third logic die 219 that faces the first wafer layer 210, the first port 51 of the first logic die 211 is disposed on a side 211a of the first logic die 211 that faces the third logic die 219. In some implementations, the first portion 51 faces the third port 53. The second port 52 of the second logic die 212 is disposed on a surface 212a of the second logic die 212 that faces the third logic die 219. In some implementations, the second port 52 faces the third port 53. In some implementations the first port 51 and the second port 52 are disposed in portions of first logic die 211 and second logic die 212 that are adjacent to one another so that a physical distance between first inter-die coupling or wiring 55 and the second inter-die coupling or wiring 57 is reduced. For example, the first inter-die coupling or wiring 55 is formed through hybrid bonding 224 between the first port 51 and the third port 53, and the second inter-die coupling or wiring 57 is formed through hybrid bonding 224 between the second port 52 and the third port 53. In this example, a 3D wafer-level packaging technology is compatible through hybrid bonding, and the physical layer connection between the third port 53 and each of the first port 51 and the second port 52 is implemented, thereby ensuring data transmission efficiency.

Further, the first port 51 of the first logic die 211 is disposed at an end portion 211ep of the first logic die 211 that is close to the second logic die 212, and the second port 52 of the second logic die 212 is disposed at an end portion 212ep of the second logic die 212 that is close to the first logic die 211. This disposition manner reduces a physical distance between the first port 51 and the second port 52 in the lateral extension direction, e.g., x-axis direction, of the first wafer layer 210, and helps reduce space occupied by the third port 53 in the extension direction of the second wafer layer 220.

In some embodiments, for a control logic configuration based on the physical layer connection, the first port 51 of the first inter-die interface 55 at the first logic die 211 may include a first interface controller 58, the second port 52 of the second inter-die interface at the second logic die 212 may include a second interface controller 59, and the first interface controller 58 and the second interface controller 59 are communicatively coupled through the third port 53.

For example, signal communications between the first interface controller 58 and the second interface controller 59 may be configured by using the physical layer connections 55, 53, 57 between the first port 51 and the second port 52, to implement data transmission control such as route control and data transmission check of a processing unit. For example, the data transmission control between the first interface controller 58 and the second interface controller 59 may be implemented by using an efficient and flexible communication protocol. For example, when the logic device 213 in the first logic die 211 needs to send data to the logic device 214 in the second logic die 212, the first interface controller 58 first sends a data request to the third port 53 on the auxiliary logic die 219 through the first inter-die interface 55. Then the data request is forwarded to the second port 52 of the second logic die 212 through the intra-die wiring 229 of the third port 53, and is further routed to the corresponding logic device 214 in the second logic die 212.

Further, the first interface controller 58 and the second interface controller 59 may be communicatively coupled by using an inter-component wiring or interconnect bus such as a universal chiplet interconnect express (Universal Chiplet Interconnect express, UCIe), for example, a UCIe 2.0 communication protocol. Protocol layers of the UCIe include a physical layer, an adaptation layer, and a transport layer. The physical layer transmits, by using wiring between the first interface controller and the second interface controller, a signal carrying data. The adaptation layer is configured to manage a link status between the first interface controller and the second interface controller, for example, CRC and a link-layer retry mechanism. The transport layer is configured to convert, for example, through data mapping or transmission channel repairing, a format of a data packet transmitted between the first interface controller 58 and the second interface controller 59 into a format suitable for transmission at the physical layer.

For example, the physical layer between the first interface controller 58 and the second interface controller 39 is formed through hybrid bonding 224 of the first inter-die coupling or wiring 55 and the second inter-die coupling or wiring 57. A signal transmission length of the physical layer is a distance between hybrid bonding points 224 of the first inter-layer wiring or coupling 55 and the second inter-die coupling or wiring 57, for example, in a range from 1 micrometer to 25 micrometers. A quantity of signal channels of the physical layer corresponds to a quantity of hybrid bonding points 224 of the first port or the second port.

Further, when the first inter-die interface 49 and the second inter-die interface 50 share the third port 53 at the auxiliary logic die 219, the third port 53 forms the data transmission path. A cable distance of the intra-die wiring 229 of the third port 53 at the auxiliary logic die 219 is greater than a coupling distance between the third port 53 and the first port 51 or the second port 52, so that a process requirement on the intra-die wiring 229 is reduced, and galvanic isolation between wires of the intra-die wiring 229 is improved. In addition, the wire distance of the intra-die wiring 229 of the third port 53 at the auxiliary logic die 219 is greater than the wire distance between the third port 53 and the first port 51 or the second port 52, which helps to reduce occupation of a high bandwidth of hybrid bonding points 224 between the first wafer layer 210 and the second wafer layer 220 by the first inter-die interface 49 and the second inter-die interface 50, so that space of the high bandwidth of the hybrid bonding points 224 between the first wafer layer 210 and the second wafer layer 220 can be used for another functional configuration of the auxiliary logic die 219.

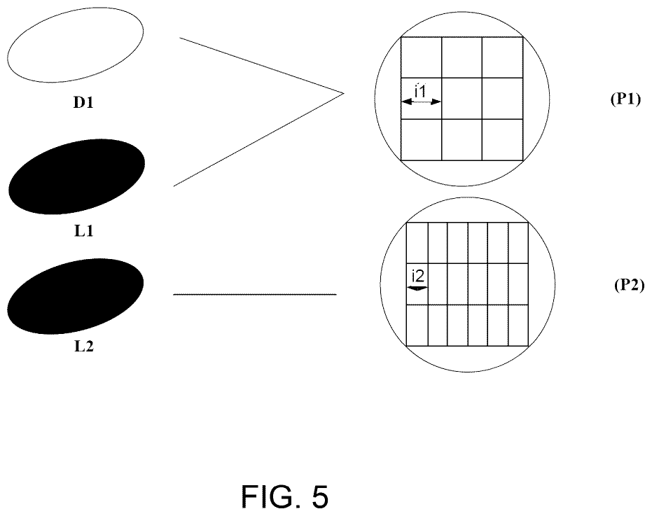

Further, as shown in FIG. 5, a process parameter of a manufacturing process (P1) of the storage die 232 at the third wafer layer 230 (e.g., D1) is i1, and a process parameter of a manufacturing process (P2) in the first logic die and the second logic die at the first wafer layer is i2. Generally, the logic process parameter i2 is less than the process parameter i1 for the storage die of memory devices, and manufacturing costs and a technical requirement of the process parameter i1 are less than manufacturing costs and a technical requirement of the process parameter i2. In some implementations, a function of the third logic die 219 at the second wafer layer 220 is different from functions of the first logic die 211 and the second logic die 212, for example, and a process parameter such as the process parameter i1 that is greater than the process parameter i2 may be used for fabricating the third logic die 219. In this case, the process parameter of the manufacturing process of the storage die 232 is compatible, and manufacturing costs of the third logic die 219 are reduced.

Some other embodiments of the present specification provide a computing device. The computing device may be any form of electronic device, such as a smartphone, a personal computer, a server, a game console, or any other device that requires a high-performance computing capability. Specifically, the computing device includes a processor card, and a chip package structure is disposed on the processor card. For example, the chip package structure may be implemented as a system on chip (System on Chip, SoC). To be specific, the system on chip implements a high-performance and high-integration electronic system design by integrating the foregoing chip package structure, and implements high-speed interconnection between chips by using the chip package structure. For applications that need to process a large amount of data, such as artificial intelligence, graphic processing, and high-performance computation, data processing efficiency can be greatly improved.

Particular embodiments of this subject are described so far. Other embodiments fall within the scope of the appended claims. In some cases, the actions recorded in the claims may be performed in a different order, and the expected result can still be achieved. In addition, the processes depicted in the accompanying drawings are not necessarily performed in the specific order or successively to achieve an expected result. In some implementations, multitasking and parallel processing may be beneficial.

It should be further noted that the terms “include”, “comprise”, or any variants thereof are intended to cover a non-exclusive inclusion. Therefore, a process, method, article, or device that includes a series of elements not only includes such elements, but also includes other elements not specified expressly, or may include inherent elements of the process, method, article, or device. Unless otherwise specified, an element limited by “include a/an . . . ” does not exclude other same elements existing in the process, the method, the article, or the device that includes the element.

The embodiments of this specification are all described in a progressive manner, for same or similar parts in the embodiments, refer to these embodiments, and descriptions of each embodiment focus on a difference from other embodiments. Especially, a system embodiment is basically similar to a method embodiment, and therefore is described briefly; for related parts, refer to partial descriptions in the method embodiment.

The foregoing descriptions are merely the embodiments of this application and are not intended to limit this application. For a person skilled in the art, various modifications and variations can be made to this application. Any modification, equivalent replacement, or improvement made without departing from the spirit and principle of this application shall fall within the scope of the claims of this application.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor structure, comprising:
a first wafer layer, the first wafer layer including a first logic die and a second logic die arranged along a first direction;
a second wafer layer, the second wafer layer including a third logic die stacked on a first side of the first wafer layer along a second direction different from the first direction;
a first inter-die interface between the first logic die and the third logic die, the first logic die electrically coupled to the third logic die through the first inter-die interface; and
a second inter-die interface between the second logic die and the third logic die, the second logic die electrically coupled to the third logic die through the second inter-die interface,
wherein the first inter-die interface and the second inter-die interface are electrically coupled to one another through an intra-die wiring in the third logic die.

2. The semiconductor structure according to claim 1, wherein the first inter-die interface and the second inter-die interface share a third port of the third logic die, and the third port includes the intra-die wiring;
the first inter-die interface includes a first port in the first logic die, the first port electrically coupled to the third port through a first inter-die coupling; and
the second inter-die interface includes a second port in the second logic die, the second port electrically coupled to the third port through a second inter-die coupling.

3. The semiconductor structure according to claim 2, wherein the third port is disposed on a surface of the third logic die that faces the first wafer layer, the first port is disposed on a surface of the first logic die that faces the second wafer layer, and the second port is disposed on a surface of the second logic die that faces the second wafer layer.

4. The semiconductor structure according to claim 3, wherein the first port of the first logic die is disposed at an end of the first logic die that is adjacent to the second logic die, and the second port of the second logic die is disposed at an end of the second logic die that is adjacent to the first logic die.

5. The semiconductor structure according to claim 3, wherein the first inter-die coupling includes a hybrid bonding between the first port and the third port, and the second inter-die coupling includes a hybrid bonding between the second port and the third port.

6. The semiconductor structure according to claim 2, wherein the first port comprises a first interface controller, the second port comprises a second interface controller, and the first interface controller and the second interface controller are communicatively coupled to one another through the third port.

7. A chip package structure, comprising:
a first semiconductor structure, comprising:
a first wafer layer including a first logic die and a second logic die arranged along a first direction;
a second wafer layer including a third logic die, the third logic die stacked on a first side of the first wafer layer;
a first inter-die interface between the first logic die and the third logic die, the first inter-die interface configured to enable data communication between the first logic die and the second logic die through the first inter-die interface; and
a second inter-die interface between the second logic die and the third logic die, the second inter-die interface configured to enable data communication between the second logic die and the third logic die through the second inter-die interface, wherein the first inter-die interface and the second inter-die interface are coupled to one another through an intra-die wiring of the third logic die; and
a package substrate, disposed on a second side of the first wafer layer.

8. The chip package structure according to claim 7, further comprising:
a second semiconductor structure, the second semiconductor structure and the first semiconductor structure disposed on a same side of the package substrate; and
an inter-component interface between the first semiconductor structure and the second semiconductor structure, the inter-component interface including inter-component wiring between the first semiconductor structure and the second semiconductor structure, the inter-component wiring configured to enable data communication between the first semiconductor structure and the second semiconductor structure through the inter-component interface.

9. The chip package structure according to claim 8, wherein the inter-component interface includes a first port in the first semiconductor structure and a second port in the second semiconductor structure, the first port and the second port coupled to one another through an internal wiring in the package substrate.

10. The chip package structure according to claim 8, further comprising an interposer between the package substrate and each of the first semiconductor structure and the second semiconductor structure,
wherein the inter-component interface includes a first port in the first semiconductor structure and a second port in the second semiconductor structure, the first port and the second port coupled to one another through an internal wiring in the interposer.

11. The chip package structure according to claim 8, wherein the first wafer layer comprises at least two logic dies, and the at least two logic dies comprise the first logic die and the second logic die; and
the inter-component interface includes a first port in the first semiconductor structure, the first port disposed on a logic die of the at least two logic dies of the first wafer layer that is close to the second semiconductor structure.

12. The chip package structure according to claim 8, wherein the second semiconductor structure comprises a third wafer layer close to the package substrate, the third wafer layer comprises at least two logic dies, and the inter-component interface includes a second port in the second semiconductor structure, the second port disposed on a logic die of the at least two logic dies of the third wafer layer that is close to the first wafer layer of the first semiconductor structure.

13. The chip package structure according to claim 7, wherein the first semiconductor structure further comprises at least one fourth wafer layer, each fourth wafer layer of the at least one fourth wafer layer including a storage die, and the at least one fourth wafer layer stacked on a side of the second wafer layer that is distal from the package substrate.

14. A semiconductor device, comprising:
a body;
a first die and a second die on the body;
a third die on the first die and the second die;
a first interface element electrically coupled between the first die and the third die; and
a second interface element electrically coupled between the second die and the third die,
wherein the first interface element and the second interface element are coupled to one another through a first wiring element within the third die.

15. The semiconductor device of claim 14, wherein an area of the third die is greater than an area of each of the first die or the second die.

16. The semiconductor device of claim 15, wherein an area of the third die is about an area of the first die and an area of the second die.

17. The semiconductor device of claim 14, wherein the wiring element within the third die is separated from a circuit device of the third die.

18. The semiconductor device of claim 14, wherein the first die includes a first circuit device electrically coupled to the first interface element, and the second die includes a second circuit device electrically coupled to the second interface element.

19. The semiconductor device of claim 14, comprising a fourth die on the body, the second die electrically coupled to the fourth die through a second wiring element in the body.

20. The semiconductor device of claim 14, wherein the first interface element includes a solder bump.
